(19) United States
(12) Patent Application Publication
(10) Pub. No.: US 2007/0194422 A1
(43) Pub. Date: Aug. 23, 2007

(54) LIGHT EMITTING DIODE PACKAGE AND FABRICATING METHOD THEREOF

(75) Inventors: Kou-Rueh Lai, Hsinchu City (TW); Gwo-Shii Yang, Hsinchu City (TW); Kung-Chi Ho, Hsinchu County (TW); Hu-Chen Tsai, Hsinchu County (TW); Wen-Chuan Wang, Hsinchu City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: NOVALITE OPTRONICS CORP., Hsinchu City (TW)

(21) Appl. No.: 11/535,991

(22) Filed: Sep. 28, 2006

(30) Foreign Application Priority Data
Feb. 23, 2006 (TW) 95106043

(51) Int. Cl. H01L 23/06

(52) U.S. Cl. 257/684

(57) ABSTRACT

A Light Emitting Diode (LED) package including a carrier, a package housing, an LED chip, and an electrostatic discharge protector (ESD protector) is provided. The package housing encapsulates a part of the carrier so as to provide a chip-accommodating space on the carrier. The LED chip disposed on the carrier and located in the chip-accommodating space is electrically connected to the carrier. The ESD protector disposed on the carrier and encapsulated by the package housing is electrically connected to the carrier. The LED package has excellent light-emitting intensity, since the light emitted from the LED chip is not absorbed by the ESD protector encapsulated by the package housing. Additionally, a fabricating method of the LED package is also provided.

### CROSS-REFERENCE TO RELATED APPLICATION

This application claims the priority benefit of Taiwan application serial no. 95106043, filed on Feb. 23, 2006. All disclosure of the Taiwan application is incorporated herein by reference.

### BACKGROUND OF THE INVENTION

1. Field of Invention

The present invention relates to a package structure and a fabricating method thereof. More particularly, the present invention relates to a light emitting diode package (LED package) having a hidden ESD protector and a fabricating method thereof.

2. Description of Related Art

Since the LED has such advantages as long service life, small volume, high shock resistance, low heat output, and low power consumption, it has been widely utilized in indicators or light sources for household appliances and various instruments. In recent years, the LED has been developed towards multicolor and high brightness; therefore, its application scope has been expanded to large outdoor display boards, traffic signal lights, and the like. In the future, it may even replace Tungsten-filament lamps and Mercury lamps to become an illumination light source with both power-saving and environment-protecting functions.

FIG. 1A shows a schematic top view of a conventional LED package. FIG. 1B shows a schematic sectional view of the LED package in FIG. 1A along Line A-A. Referring to FIGS. 1A and 1B at the same time, the conventional LED 100 includes a lead frame 110, a package housing 120, an LED chip 130, an ESD protector 140, a plurality of bonding wires 150, and an encapsulant 160. The package housing 120 encapsulates a part of the lead frame 110, so as to form a chip-accommodating space S on the lead frame 110. The LED chip 130 and the ESD protector 140 are disposed on the lead frame 110 and located in the chip-accommodating space S. The LED chip 130 and the ESD protector 140 are respectively electrically connected to the lead frame 110 via the bonding wires 150. The ESD protector is employed in the LED package to protect the Light Emitting Diode from ESD damage over the process of further assembly of the LED. Moreover, the encapsulant 160 encapsulates the LED chip 130, ESD protector 140, and bonding wires 150.

When the LED chip 130 of the conventional LED package 100 is driven by current to emit light, a part of the light emitted by the LED chip 130 is reflected by the white package housing 120 and then emitted from the transparent encapsulant 160 in a direction away from the lead frame 110. Since the ESD protector 140 of the conventional LED package 100 is a non-transparent device, when the LED chip 130 is driven by current to emit light, the non-transparent ESD protector 140 will absorb a part of the light emitted by the LED chip 130. Therefore, the light-emitting intensity of the conventional LED package 100 may be reduced by the non-transparent ESD protector 140. Also, the geometry of the light emitted from the conventional LED could be distorted due to the as-centered position of the Diode.

### SUMMARY OF THE INVENTION

An object of the present invention is to provide an LED package. An ESD protector is buried within the package housing, so that the ESD protector will not affect the light-emitting intensity as well as the light shape of the LED package.

Another object of the present invention is to provide a fabricating method of an LED package, so as to bury the ESD protector inside the package housing, thereby improving the light-emitting intensity of the LED package.

To achieve the aforementioned and other objects, the present invention provides an LED package, including a carrier, a package housing, an LED chip, and an ESD protector. The package housing encapsulates a part of the carrier to form a chip-accommodating space on the carrier. The LED chip disposed on the carrier and located in the chip-accommodating space is electrically connected to the carrier. The ESD protector disposed on the carrier and encapsulated by the package housing is electrically colmected to the carrier.

In one embodiment of the present invention, the above-mentioned ESD protector and the LED chip are, for example, disposed on the same surface of the carrier.

In one embodiment of the present invention, the above-mentioned ESD protector and the LED chip are, for example, respectively disposed on the two opposite surfaces of the carrier.

In one embodiment of the present invention, the above-mentioned LED package further includes at least one bonding wire, wherein the ESD protector is electrically connected to the carrier via the bonding wire(s), and the package housing encapsulates the bonding wire(s).

In one embodiment of the present invention, the above-mentioned LED package further includes a plurality of bumps, wherein the ESD protector is electrically connected to the carrier through the bumps, and the package housing encapsulates the bumps.

In one embodiment of the present invention, the above-mentioned ESD protector is a Zener Diode chip, red-light LED chip, SMD type Zener Diode package, SMD type red-light LED package, Capacitor, Varistor, or Surge absorber.

In one embodiment of the present invention, the above-mentioned carrier is, for example, a lead frame.

In one embodiment of the present invention, the above-mentioned carrier is, for example, a lead frame. Moreover, the package housing can encapsulate parts of the regions of the two opposite surfaces of the carrier.

In one embodiment of the present invention, the above-mentioned carrier is, for example, a package substrate.

In one embodiment of the present invention, the above-mentioned carrier is, for example, a package substrate. Moreover, the package housing can encapsulate at least a part of the region of one surface of the carrier.

In one embodiment of the present invention, the above-mentioned LED further includes at least one bonding wire, wherein the LED chip is electrically connected to the carrier through the bonding wire(s).

In one embodiment of the present invention, the above-mentioned LED further includes a plurality of bumps, wherein the LED chip is electrically connected to the carrier through the bumps.

In one embodiment of the present invention, the above-mentioned LED further includes an encapsulant, which can encapsulate the LED chip and the carrier exposed by the chip-accommodating space.

In one embodiment of the present invention, the above-mentioned LED further includes a Phosphor doped encapsulant, which can encapsulate the LED chip and the carrier exposed by the chip-accommodating space.

In one embodiment of the present invention, the material of the above-mentioned package housing is, for example, plastic, metal, or metal oxide.

To achieve the aforementioned and other objects, the present invention provides a fabricating method of an LED package including the following steps. First, a carrier is provided, and then an ESD protector is disposed on the carrier. Next, the ESD protector is electrically connected to the carrier and a package housing bonded to the carrier is formed, wherein the package housing encapsulates the ESD protector and a part of the carrier so as to form a chip-accommodating space on the carrier. After that, an LED chip is disposed on the carrier exposed by the chip-accommodating space. Then, the LED chip is electrically connected to the carrier.

In one embodiment of the present invention, the above-mentioned ESD protector and the LED chip are, for example, disposed on the same surface of the carrier.

In one embodiment of the present invention, the above-mentioned ESD protector and the LED chip are, for example, respectively disposed on the two opposite surfaces of the carrier.

In one embodiment of the present invention, the above-mentioned ESD protector is, for example, disposed on the carrier and electrically connected to the carrier via SMD type technology.

In one embodiment of the present invention, the above-mentioned ESD protector is, for example, disposed on the carrier and electrically connected to the carrier via flip chip bonding technology.

In one embodiment of the present invention, the above-mentioned ESD protector is, for example, electrically connected to the carrier via wire bonding technology.

In one embodiment of the present invention, the above-mentioned LED chip is, for example, disposed on the carrier and electrically connected to the carrier via flip chip bonding technology.

In one embodiment of the present invention, the above-mentioned LED package is, for example, electrically connected to the carrier via wire bonding technology.

In one embodiment of the present invention, the above-mentioned fabricating method of an LED package further includes forming an encapsulant to encapsulate the LED chip and the carrier exposed by the chip-accommodating space after the step of electrically connecting the LED chip and the carrier.

In one embodiment of the present invention, the above-mentioned fabricating method of an LED package further includes forming a Phosphor doped encapsulant for encapsulating the LED chip and the carrier exposed by the chip-accommodating space after the step of electrically connecting the LED chip and the carrier.

In view of the above, the LED package of the present invention and the fabricating method thereof can use the package housing to encapsulate the ESD protector. Therefore, when the LED chip emits light, the non-transparent ESD protector will not reduce the light-emitting intensity of the LED package.

In order to the make the aforementioned and other objects, features, and advantages of the present invention comprehensible, preferred embodiments accompanied with figures are described in detail below.

### BRIEF DESCRIPTION OF THE DRAWINGS

FIG. 1A shows a schematic top view of a conventional LED package;

FIG. 1B shows a schematic sectional view of the LED package in FIG. 1A along Line A-A;

FIG. 2A shows a schematic top view of an LED package according to the first embodiment of the present invention;

FIG. 2B shows a schematic sectional view of the LED package in FIG. 2A along Line B-B;

FIG. 3 shows a schematic sectional view of another type of LED package according to the first embodiment of the present invention;

FIG. 4A-4E show schematic views of the fabricating method of the LED package according to the first embodiment;

FIG. 5A shows a schematic top view of an LED package according to the second embodiment of the present invention;

FIG. 5B shows a schematic sectional view of the LED package in FIG. 5A along Line C-C;

FIG. 6 shows a schematic sectional view of an LED package according to the third embodiment of the present invention.

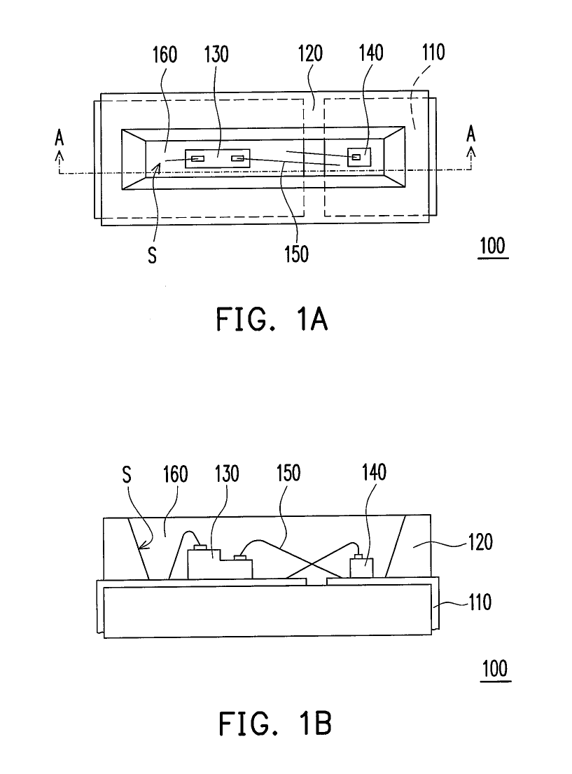

### DESCRIPTION OF EMBODIMENTS

### The First Embodiment

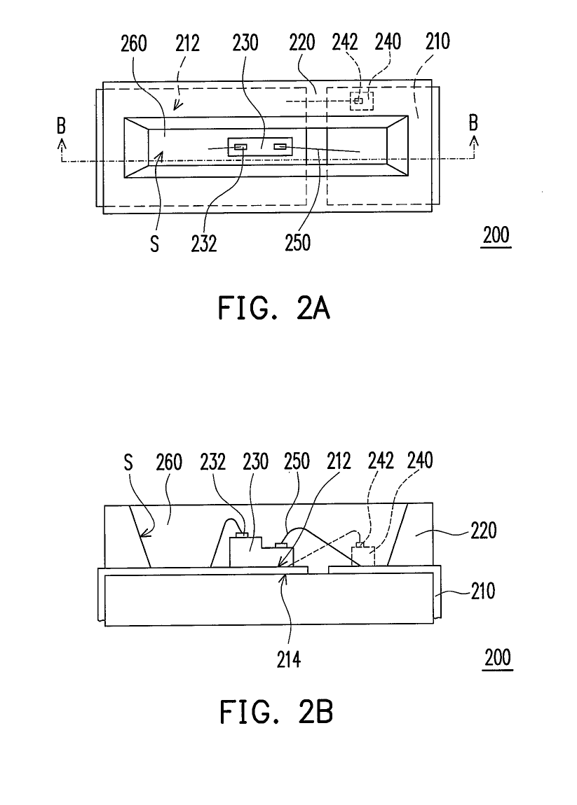

FIG. 2A shows a schematic top view of an LED package according to the first embodiment of the present invention. FIG. 2B shows a schematic sectional view of the LED package in FIG. 2A along Line B-B. Referring to FIGS. 2A and 2B at the same time, the LED package 200 of the first embodiment includes a carrier 210 (for example, a Lead Frame), a package housing 220 (the material thereof can be plastic, metal, or metal oxide), an LED chip 230, and an ESD protector 240. The package housing 220 encapsulates a part of the carrier 210 to form a chip-accommodating space S on the carrier 210. The LED chip 230 disposed on the carrier 210 and located in the chip-accommodating space S is electrically connected to the carrier 210. Furthermore, the ESD protector 240 disposed on the carrier 210 and encapsulated by the package housing 220 is electrically connected to the carrier 210.

In one embodiment of the present invention, the ESD protector 240 can be a one-directional ESD protector. In this case, the ESD protector 240 and the LED chip 230 are reversely connected in parallel. When the voltage between both ends (the positive and the negative electrodes) of the LED chip 230 does not exceed the operating voltage of the LED chip 230, the current flows through the LED chip 230 to forward the LED chip 230 to emit light. At this time, the ESD protector 240 reversely connected to the LED chip 230 in parallel does not function. On the contrary, when the ESD phenomenon occurs, the voltage between both ends (the positive and the negative electrodes) of the LED chip 230 exceeds the break-down voltage of the LED chip 230. At this time, the ESD protector 240 can quickly conduct the high-voltage static electricity away to prevent the LED chip 230 from the damage of high-voltage static electricity.

In view of the above, the ESD protector 240 used in the present invention can also be a bidirectional ESD protector usually connected to the LED chip 230 in parallel, so as to ensure that the LED chip 230 will not be damaged by the forward and reverse static electricity.

When the LED chip 230 of the LED package 200 is driven by current to emit light, a part of the light emitted by the LED chip 230 is reflected by usually a white or other package housing 220 that can reflect light, and is thereby emitted away from the carrier 210. However, as the non-transparent ESD protector 240 of the present invention is encapsulated by the package housing 220 (i.e. the ESD protector 240 cannot be seen from the appearance of the LED package 200), when the LED chip 230 is driven by current to emit light, the non-transparent ESD protector 240 will not absorb the light emitted by the LED chip 230, and thereby the light-emitting intensity of the LED package 200 will not be affected.

In particular, the ESD protector 240 and the LED chip 230 of the present embodiment can be disposed on the same surface of the carrier 210. Seen from FIGS. 2A and 2B, the LED package 200 of the present embodiment further includes at least one bonding wire 250 (three bonding wires are shown in FIGS. 2A and 2B). The ESD protector 240 and the LED chip 230 can be electrically connected to the carrier 210 via the bonding wires 250 respectively; in other words, the ESD protector 240 and LED chip 230 are respectively electrically connected to the carrier 210 by wire bonding technology. Moreover, the package housing 220 of the present embodiment not only encapsulates the bonding wires 250 electrically connected between the ESD protector 240 and the carrier 210, but also encapsulates parts of the regions on the two opposite surfaces 212 and 214 of the carrier.

The ESD protector 240 can be a Zener Diode chip, red-light LED chip, SMD type Zener Diode package, SMD type red-light LED package, Capacitor, Varistor, or Surge Absorber. If the ESD protector 240 is a Zener Diode chip or a red-light LED chip, the ESD protector 240 can be electrically connected to the carrier 210 by wire bonding or flip chip bonding technology. If the ESD protector 240 is a SMD type Zener Diode chip or a SMD type red-light LED chip, the ESD protector 240 can be directly electrically connected to the carrier 210 through solder paste. If the ESD protector 240 is a Varistor, the function of the ESD protector 240 is to provide high resistor protection or Varistor protection (the latter is that the Varistor is conductive at a certain voltage). It should be illustrated that for purpose of convenience, the ESD protector 240 of the chip type (i.e. the Zener Diode chip or the red-light LED chip) will be taken as an example in the following part of the present embodiment.

It should be noted that in the first embodiment, the positions of the bonding pads 232 of the LED chip 230 are different from that of the bonding pads 242 of the ESD protector 240. However, the type of the LED chip 230 and the ESD protector 240 can be altered according to design requirements. For example, the LED chip 230 can employ the type of the ESD protector 240, while the ESD protector 240 can employ the type of the LED chip 230 (not shown). Furthermore, in the present embodiment, the LED package 200 can further include an encapsulant 260 encapsulating the LED chip 230 and the carrier 210 exposed by the chip-accommodating space S and further encapsulating the bonding wires 250 electrically connected between the LED chip 230 and the carrier 210. The encapsulant 260 can protect the encapsulated devices from being affected by the external temperature, humidity, and noise. Additionally, the encapsulant 260 can be doped with Phosphor, so when the LED chip 230 of the LED package 200 emits light, the Phosphor is activated by the LED chip 230 to emit visible light of another color. Therefore, the LED package 200 can produce light-mixing effect (for example, white light) via mixing the lights emitted by the LED chip 230 and the Phosphor.

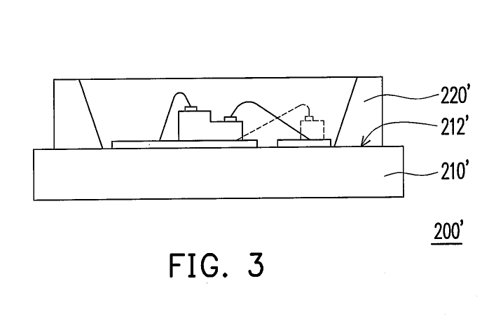

Referring to FIG. 3, it shows a schematic sectional view of another type of LED package according to the first embodiment of the present invention. The LED package 200′ in FIG. 3 is similar to the LED package 200 in FIG. 2, except for the major difference that the carrier 210′ of the LED package 200′ is a package substrate, and the package housing 220′ only encapsulates a part of the region on the surface 212′ of the carrier 210′. It should be illustrated that for purpose of convenience, a Lead Frame is taken as an example in the following part of the present embodiment.

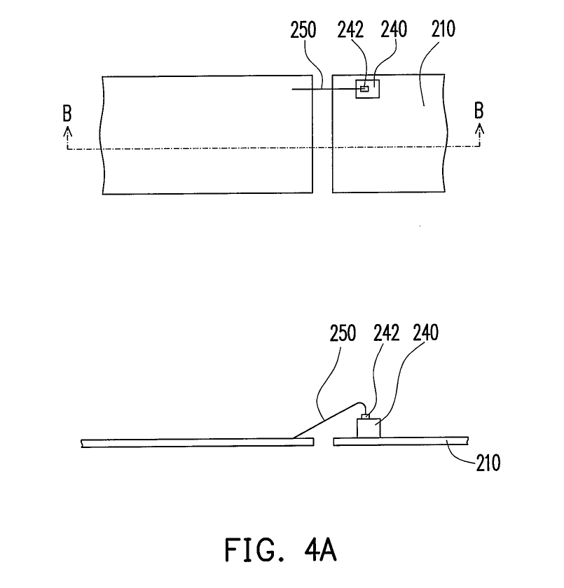

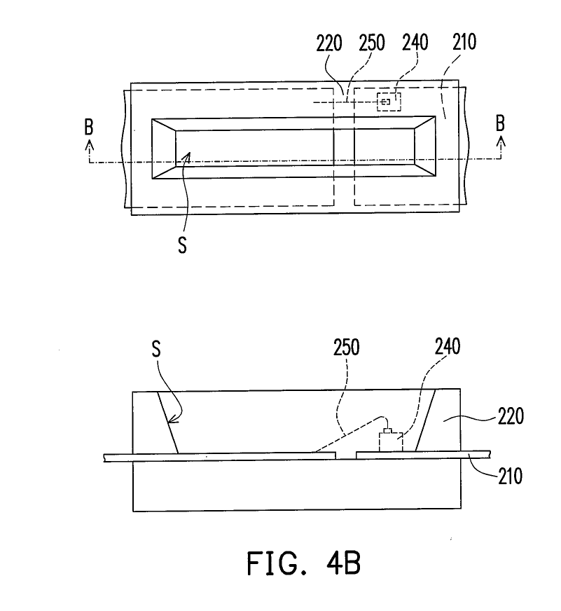

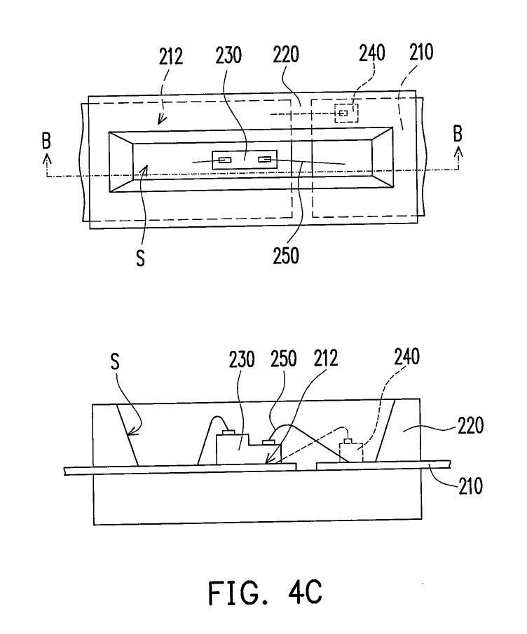

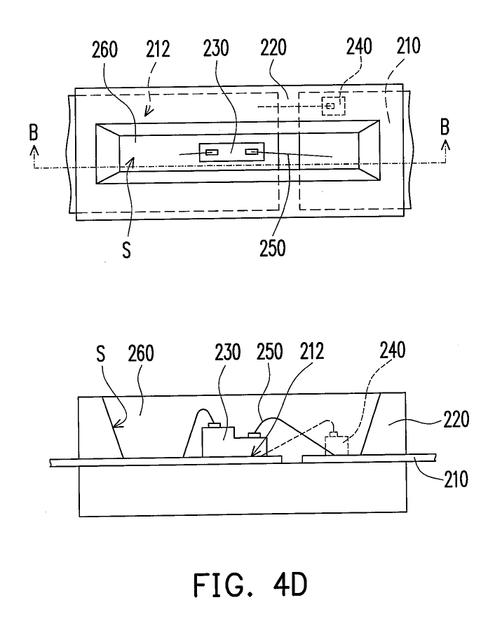

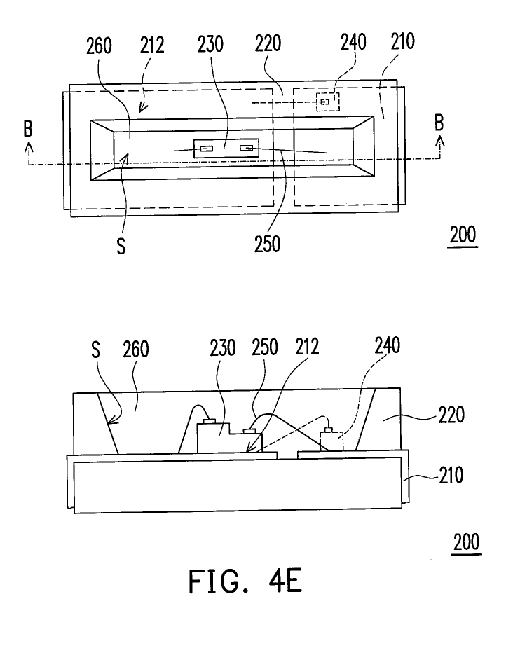

The fabricating method of the LED package 200 will be described below. FIG. 4A-4E show schematic views of the fabricating method of the LED package according to the first embodiment, wherein each of FIG. 4A-4E shows a schematic top view and a schematic sectional view along Line B-B. The fabricating method of the LED package 200 according to the present embodiment includes the following steps. First, referring to FIG. 4A, a carrier 210 (Lead Frame) is provided. The Lead Frame can be formed via a punching process or an etching process. The Lead Frame is usually provided with two pins as it is used to carry the LED chip 230. Then, an ESD protector 240 is disposed on the carrier 210. The ESD protector 240 is usually provided with a bonding pad 242, and can be disposed on the carrier 210 via a conductive encapsulant (such as Silver paste) (not shown). Next, the ESD protector 240 is electrically connected to the carrier 210 via, for example, wire bonding technology. Therefore, both ends of the ESD protector 240 are respectively electrically connected to the carrier 210 via a bonding wire 250 and a conductive encapsulant.

Furthermore, referring to FIG. 4B, a package housing 220 bonded to the carrier 210 is formed, wherein the package housing 220 encapsulates the ESD protector 240 and a part of the carrier 210, so as to form a chip-accommodating space S on the carrier 210. In the first embodiment, the package housing 220 can be formed by a mold (not shown) through a plastics injection molding process or a die casting molding process. The shape of the internal mold cavity may affect the shape of the package housing 220, and the shape of the package housing 220 of the present embodiment is used as an example rather than to limit the present invention. After the above processes, the package housing 220 can further encapsulate the bonding wire 250 electrically connected between the ESD protector 240 and the carrier 210.

After that, referring to FIG. 4C, an LED chip 230 is, for example, disposed on the carrier 210 exposed by the chip-accommodating space S via a conductive encapsulant (not shown). Here, the conductive encapsulant functions as a medium for the LED chip 230 to conduct heat to the carrier 210. Then, the LED chip 230 is electrically connected to the carrier 210 via, for example, wire bonding technology; i.e. the LED chip 230 is electrically connected to the carrier 210 via another two bonding wires 250. In the first embodiment, the ESD protector 240 and the LED chip 230 are, for example, disposed on the same surface 212 of the carrier 210.

After the above step of electrically connecting the LED chip 230 to the carrier 210, referring to FIG. 4D, the fabricating method of the LED package 200 according to the first embodiment further includes forming an encapsulant 260, for example, in a manner of dispensing (the encapsulant 260 can be doped with Phosphor). The encapsulant 260 can encapsulate the LED chip 230 and the carrier 210 exposed by the chip-accommodating space S, and can further encapsulate the bonding wires 250 electrically connected between the LED chip 230 and the carrier 210. Then, referring to FIG. 4E, the fabricating method of the LED package 200 according to the first embodiment further includes steps of trimming and forming. The purpose of trimming is to separate a plurality of encapsulated finished products on the carrier 210. The purpose of forming is to form the part of the carrier 210 exposed out of the package housing 220 and the encapsulant 260 into a designed shape, so as to electrically connect the electronic device at the next level (not shown). Through the above steps, the LED package 200 is formed.

It should be illustrated that the step of forming the package housing 220 bonded to the carrier 210 as shown in FIG. 4B can be performed only after the three steps shown in FIG. 4A. In other words, for example, in the fabricating method according to another embodiment of the present invention, the step shown in FIG. 4C can be performed before the step shown in FIG. 4B, i.e. the LED chip 230 is first disposed on the predetermined carrier 210 exposed by the chip-accommodating space S, and then electrically connected to the carrier 210. After that, the package housing 220 bonded to the carrier 210 is formed, wherein the package housing 220 encapsulates the ESD protector 240 and a part of the carrier 210, so as to form a chip-accommodating space S on the carrier 210.

### The Second Embodiment

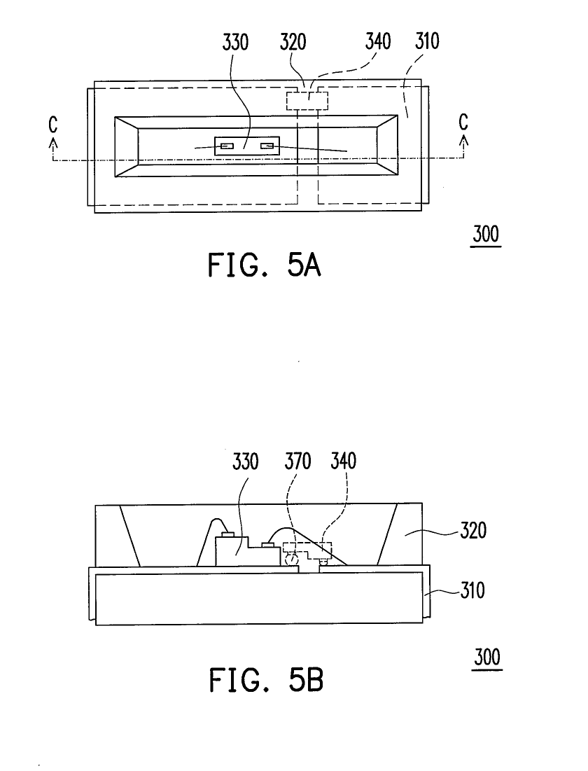

FIG. 5A shows a schematic top view of an LED package according to the second embodiment of the present invention. FIG. 5B shows a schematic sectional view of the LED package in FIG. 5A along Line C-C. Referring to FIGS. 2A, 2B, 5A, and 5B at the same time, the major difference between the LED package 300 of the second embodiment and the LED package 200 of the first embodiment is that the LED package 300 further includes a plurality of bumps 370. The ESD protector 340 can be electrically connected to the carrier 310 through the bumps 370, and the package housing 320 encapsulates the bumps 370. In other words, the ESD protector 340 is disposed on the carrier 310 and electrically connected to the carrier 310 via flip chip bonding technology.

It should be illustrated that, in the second embodiment, the LED chip 330 and the ESD protector 340 of the LED package 300 are electrically connected to the carrier 310 in different ways, and the two electrical connection manners can be altered according to design requirements. For example, the LED chip 330 can employ the electrical connection manner used by the ESD protector 340, while the ESD protector 340 can employ the electrical connection manner used by the LED chip 330 (not shown).

### The Third Embodiment

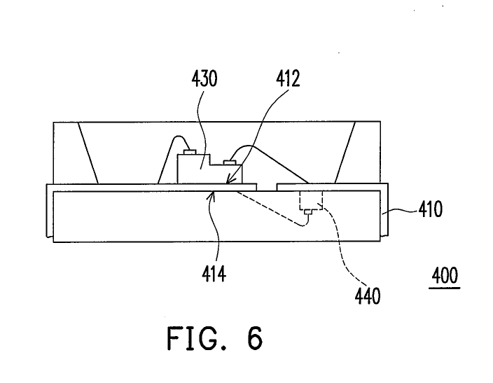

FIG. 6 shows a schematic sectional view of an LED package according to the third embodiment of the present invention. Referring to FIGS. 2A, 2B, and 6, the difference between the LED package 400 of the third embodiment and the LED package 200 of the first embodiment is that the LED chip 430 and the ESD protector 440 are, for example, respectively disposed on the two opposite surfaces 412 and 414 of the carrier 410.

In view of the above, the LED package and the fabricating method thereof according to the present invention have at least the following advantages.

For the LED package and the fabricating method thereof according to the present invention, the ESD protector can be encapsulated by the package housing, so when the LED chip is driven by the current to emit light, the non-transparent ESD protector will not absorb the light emitted by the LED chip, and thereby the light-emitting intensity of the LED package will not be affected.

Since the volume of the ESD protector is small, in the fabricating method of the LED package according to the present invention, the size of the package housing is not necessary to be adjusted as the ESD protector is encapsulated by the package housing. Thus, the fabricating method of the LED package according to the present invention can be integrated with existing processes without increasing the fabricating cost.

Though the present invention has been disclosed above with preferred embodiments, these are not intended to limit the present invention. Anybody skilled in the art can make some modifications and variations without departing from the spirit and scope of the invention. Therefore, the protecting range of the invention falls in the appended claims.

What is claimed is:

1. A Light-Emitting Diode (LED) package, comprising:
a carrier;
a package housing, encapsulating a part of the carrier, so as to form a chip-accommodating space on the carrier;
an LED chip, disposed on the carrier and located in the chip-accommodating space, wherein the LED chip is electrically connected to the carrier; and
an electrostatic discharge protector (ESD protector), disposed on the carrier and encapsulated by the package housing, wherein the ESD protector is electrically connected to the carrier.

2. The LED package as claimed in claim 1, wherein the ESD protector and the LED chip are disposed on the same surface of the carrier.

3. The LED package as claimed in claim 1, wherein the ESD protector and the LED chip are respectively disposed on the two opposite surfaces of the carrier.

4. The LED package as claimed in claim 1, further comprising at least one bonding wire, wherein the ESD protector is electrically connected to the carrier via the bonding wire, and the package housing encapsulates the bonding wire.

5. The LED package as claimed in claim 1, further comprising a plurality of bumps, wherein the ESD protector is electrically connected to the carrier via the bumps, and the package housing encapsulates the bumps.

6. The LED package as claimed in claim 1, wherein the ESD protector is a Zener Diode chip, red-light LED chip, SMD type Zener Diode package, SMD type red-light LED package, Capacitor, Varistor, or Surge Absorber.

7. The LED package as claimed in claim 1, wherein the carrier is a Lead Frame.

8. The LED package as claimed in claim 7, wherein the package housing encapsulates parts of the regions of the two opposite surfaces of the carrier.

9. The LED package as claimed in claim 1, wherein the carrier is a package substrate.

10. The LED package as claimed in claim 9, wherein the package housing encapsulates at least part of the region of one surface of the carrier.

11. The LED package as claimed in claim 1, further comprising at least one bonding wire, wherein the LED chip is electrically connected to the carrier through the bonding wire.

12. The LED package as claimed in claim 1, further comprising a plurality of bumps, wherein the LED chip is electrically connected to the carrier via the bumps.

13. The LED package as claimed in claim 1, further comprising an encapsulant, wherein the encapsulant encapsulates the LED chip and the carrier exposed by the chip-accommodating space.

14. The LED package as claimed in claim 1, further comprising a Phosphor doped encapsulant for encapsulating the LED chip and the carrier exposed by the chip-accommodating space.

15. The LED package as claimed in claim 1, wherein the material of the package housing comprises plastic, metal, or metal oxide.

16. A fabricating method of an LED package, comprising:
providing a carrier;
disposing an ESD protector on the carrier;
electrically connecting the ESD protector to the carrier;
forming a package housing bonded to the carrier, wherein the package housing encapsulates the ESD protector and a part of the carrier, so as to form a chip-accommodating space on the carrier;
disposing an LED chip on the carrier exposed by the chip-accommodating space; and
electrically connecting the LED chip to the carrier.

17. The fabricating method of an LED package as claimed in claim 16, wherein the ESD protector and the LED chip are disposed on the same surface of the carrier.

18. The fabricating method of an LED package as claimed in claim 16, wherein the ESD protector and the LED chip are respectively disposed on the two opposite surfaces of the carrier.

19. The fabricating method of an LED package as claimed in claim 16, wherein the ESD protector is disposed on the carrier and electrically connected to the carrier via SMD type technology.

20. The fabricating method of an LED package as claimed in claim 16, wherein the ESD protector is disposed on the carrier and electrically connected to the carrier via flip chip bonding technology.

21. The fabricating method of an LED package as claimed in claim 16, wherein the ESD protector is electrically connected to the carrier via wire bonding technology.

22. The fabricating method of an LED package as claimed in claim 16, wherein the LED chip is disposed on the carrier and electrically connected to the carrier via flip chip bonding technology.

23. The fabricating method of an LED package as claimed in claim 16, wherein the LED package is electrically connected to the carrier via wire bonding technology.

24. The fabricating method of an LED package as claimed in claim 16, further comprising forming an encapsulant to encapsulate the LED chip and the carrier exposed by the chip-accommodating space after electrically connecting the LED chip to the carrier.

25. The fabricating method of an LED package as claimed in claim 16, further comprising forming a Phosphor doped encapsulant to encapsulate the LED chip and the carrier exposed by the chip-accommodating space after electrically connecting the LED chip to the carrier.

26. The fabricating method of an LED package as claimed in claim 16, wherein the package housing bonded to the carrier is formed by a plastics injection molding process or a die casting molding process.
